(19) United States
(12) Patent Application Publication
(10) Pub. No.: US 2026/0282295 A1
(43) Pub. Date: Sep. 17, 2026

(54) TAPE LIBRARY WITH VARIABLE SPEED AIR CONDITIONER

(71) Applicant: INTERNATIONAL BUSINESS MACHINES CORPORATION, Armonk, NY (US)

(72) Inventors: Shawn M. Nave, Tucson, AZ (US); Leonard G. Jesionowski, Tucson, AZ (US)

(21) Appl. No.: 19/079,569

(22) Filed: Mar. 14, 2025

(51) Int. Cl. H05K 7/20

(52) U.S. Cl. CPC H05K 7/20836; H05K 7/20354; H05K 7/20827

(57) ABSTRACT

Embodiments of the present invention include a method for managing temperature and humidity levels within a tape library utilizing a variable speed air conditioning unit. The method includes receiving environmental values for an internal environment of an enclosure of a tape library. The method further includes determining the environmental values are approaching a target temperature for the enclosure of the tape library. The method further includes reducing or increasing an original output of a compressor and a fan speed of a variable speed air conditioning unit of the tape library to a new output.

### BACKGROUND

This disclosure relates generally to tape libraries, and in particular to tape libraries with an integrated variable speed air conditioner.

Automated tape libraries are commonly utilized to store a large quantity of data in a cost effective manner. Deploying a tape library at a customer site typically requires restrictive temperature and humidity limits in which the product can operate. Furthermore, the restrictive temperature and humidity limits are different when compared to other information technology (IT) equipment, such as, servers utilizing high end disk or flash storage. Deploying the tape library at the customer site allows for low cost data storage and a low energy usage solution which can operate alongside the existing IT equipment. The restrictive requirements for the temperature and humidity limits are achieved utilizing an air conditioning unit to regulate the temperature and humidity levels within the tape library.

Embodiments in accordance with the present invention disclose a method, computer program product and computer system for managing temperature and humidity levels within a tape library utilizing a variable speed air conditioning unit, the method, computer program product and computer system can receive environmental values for an internal environment of an enclosure of a tape library. The method, computer program product and computer system can determine the environmental values are approaching a target temperature for the enclosure of the tape library. The method, computer program product and computer system can reduce or increase an original output of a compressor and a fan speed of a variable speed air conditioning unit of the tape library to a new output.

### BRIEF DESCRIPTION OF THE SEVERAL VIEWS OF THE DRAWINGS

FIG. 1 is a functional block diagram illustrating a computing environment, in accordance with an embodiment of the present invention.

FIG. 2 depicts a flowchart of a variable speed air conditioning unit program for managing temperature and humidity levels within a tape library utilizing a variable speed air conditioning unit profile, in accordance with an embodiment of the present invention.

FIG. 3 depicts a flowchart of a variable speed air conditioning unit program for modulating compressor and fan speed output utilizing a variable speed air conditioning unit profile, in accordance with an embodiment of the present invention.

FIG. 4 depicts a side cutaway view of a tape library with an air conditioning unit operating with a variable speed air conditioning unit program, in accordance with an embodiment of the present invention.

FIG. 5 depicts a side cutaway view for airflow internal and external to a tape library with an air conditioning unit operating with a variable speed air conditioning unit program, in accordance with an embodiment of the present invention.

### DETAILED DESCRIPTION

Existing solutions for storing tape in an automated tape library with an air conditioning unit include the challenges of maintaining a consistent temperature and humidity level within the automated tape library. The challenges are even greater when the automated tape library is to operate in a humid environment, where humid air can seep into the automated tape library from an external environment. One of the challenges of maintaining the consistent temperature and humidity level occurs when a compressor and fans of the air conditioning unit are operational, where the air conditioning unit is both cooling the air and removing moisture from the air within the automated tape library. When a temperature reaches a set value within the automated tape library, the air conditioning unit deactivates by turning off the compressor. When the compressor turns off, evaporator coils of the air conditioning unit where moisture is adhered to warms up, and the moisture is released from the evaporator coils of the air conditioning unit into the air stream. As a result, there is a momentary and significant burst of humidity introduced into the internal environment of the automated tape library, where due to the limited volume of air within the automated tape library the effect is magnified.

The limited volume of air within the automated tape library and a size of the air conditioning unit required to provide cooling for extreme environments (i.e., high heat and/or high humidity), results in large humidity variations in the internal environment of the automated tape library due to an undesirable amount of moisture being trapped and released by the evaporator coils. As the air conditioning unit of the automated tape library operates there are numerous on/off cycles that occur in given day, which translates into numerous cycles of a period of high humidity that is subsequently followed by a drying cycle where humidity levels drop within the internal environment of the automated tape library. This constant cycle between humidity levels is not desirable for the long term reliability of the tape media. A desirable environment for the tape media for long term reliability and storage includes an internal environment of the automated tape library that includes steady temperature and humidity levels, without the constant cycling between humidity levels. Embodiments of the present invention provide a solution to maintain a constant internal environment within the automated tape library that allow the automated tape library to operate in external environments outside of its normal operating range.

Adding an air conditioning unit to an automated tape library requires that an internal environment of an enclosure for the automated tape library be sealed from an external environment. The automated tape library typically includes perforated areas to allow ambient air to flow through and cool tape drives which generate heat during normal operations of reading and writing data. Though there are attempts to seal the internal environment of the automated tape library from the external environment, various openings are present on the enclosure and through cable access apertures. Cables such as power, ethernet, or other types of data cables are required to enter and exit the enclosure of the automated tape library to support the operations of the tape drives. Creating a seal around each cable is typically not achieved, especially when the cables are supplied by the customer where the enclosure of the automated tape library is not designed for each of the various cable configurations.

Due to the ability for external ambient air to enter the enclosure of the automate tape library when the external ambient air is high temperature and high humidity, there is a need for the air conditioning unit to operate to remove moisture from the air as it cools. Humidity levels are lowered by having the moisture condense onto cold evaporator coils of the air conditioning unit through which the air is flowing through. Moisture condensing onto the cold evaporator coils allows for the moisture to be released into the air stream when the compressor turns off, thus rapidly raising the humidity level inside the automated tape library until the humidity level is subsequently lowered again. This cycle of rapid humidity level rise and subsequent lowering of humidity levels occurs each time the compressor of the air conditioning unit powers on and off. Instances can occur where the humidity level of the internal ambient air within the automated tape library can rapidly rise to a level that can exceed even the external ambient air relative humidity level. Furthermore, instances can occur where condensation forms on cooled surfaces within the enclosure of the automated tape library when the humid air comes in contact with the cooled surfaces.

Embodiments of the present invention provide an automated tape library with a variable speed air conditioning unit for reducing an amount of moisture being introduced into an air stream of an internal environment of the automated tape library. Rather than powering off a compressor of the air conditioning unit when a temperature level approaches a target value, embodiments of the present invention gradually ramp down the compressor and fans of the air conditioning unit. The gradual ramp down of the compressor and fans allows for the evaporator coils to warm up slowly, thus reducing an immediate release of a large amount of moisture back into the air stream. Additionally, the variable speed fans can affect a total cooling capacity of the air conditioning unit in a manner that allows the compressor to continue operating, thus keeping the evaporator coils cool even in environments where a traditional air conditioning unit would power off the compressor.

The automated tape library with the variable speed air conditioning unit provide advantages including but not limited to reducing overall energy consumption, longer lifespan of components withing the air conditioning unit, and reducing noise when operating during the gradual ramp down phase of the compressor and fans. Since the automated tape library utilizes an enclosure with a limited volume of air that requires cooling, the variable speed air conditioning unit can gradually move the internal environment of the automated tape library to a desired temperature and humidity range by performing incremental adjustments to the compressor and the fan speed. The incremental adjustments allow for gradual changes to the internal environment of the tape library which is optimal for long term life and performance of the tape media and the tape drives.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments. It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

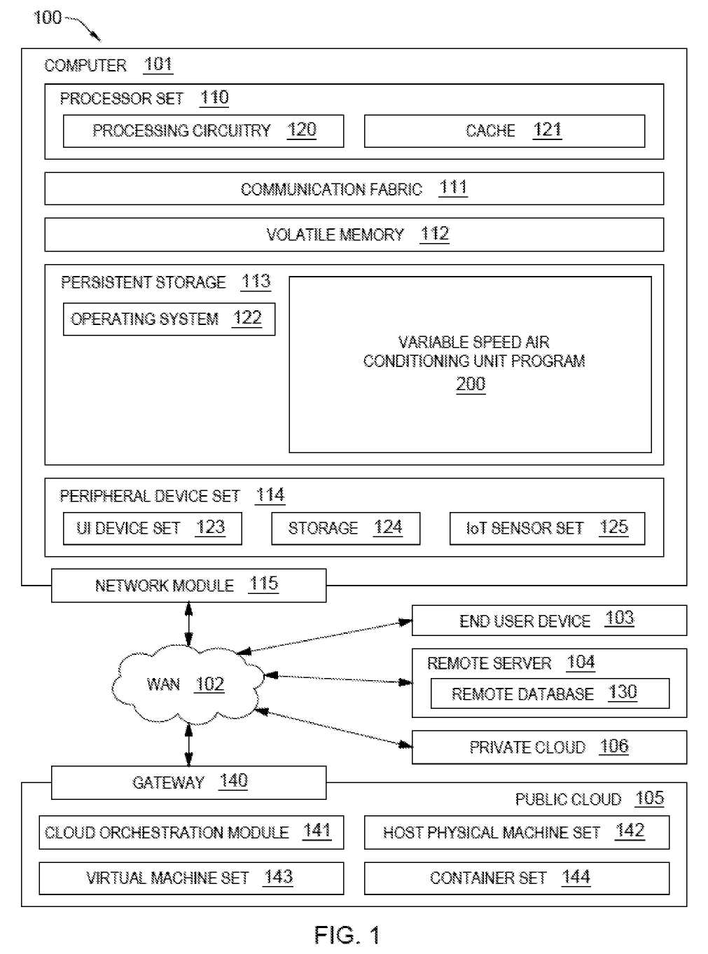

FIG. 1 is a functional block diagram illustrating a computing environment, generally designated 100, in accordance with one embodiment of the present invention. FIG. 1 provides only an illustration of one implementation and does not imply any limitations with regard to the environments in which different embodiments may be implemented. Many modifications to the depicted environment may be made by those skilled in the art without departing from the scope of the invention as recited by the claims.

Computing environment 100 contains an example of an environment for the execution of at least some of the computer code involved in performing the inventive methods, such as, variable speed air conditioning unit program 200. In addition to variable speed air conditioning unit program 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and variable speed air conditioning unit program 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in variable speed air conditioning unit program 200 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input / output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in variable speed air conditioning unit program 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

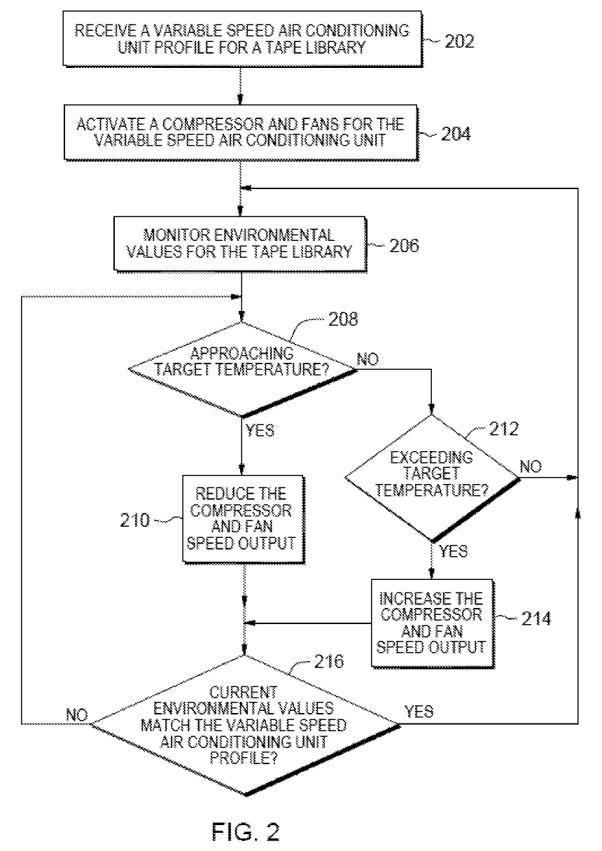

FIG. 2 depicts a flowchart of a variable speed air conditioning unit program for managing temperature and humidity levels within a tape library utilizing a variable speed air conditioning unit profile, in accordance with an embodiment of the present invention.

Variable speed air conditioning unit program 200 receives a variable speed air conditioning unit profile for a tape library (202). In this embodiment, the variable speed air conditioning unit profile provides operational parameters for a compressor and fans of a variable speed air conditioning unit based on environmental values within an enclosure of the tape library. Since the tape library has specific temperature and humidity requirements, variable speed air conditioning unit program 200 utilizes the variable speed air conditioning unit profile for gradually reducing or increasing an output of the compressor and the fan speed to ensure a temperature and humidity level of the environmental values within the enclosure adhere to the specific temperature and humidity requirements. Each variable speed air conditioning unit profile is specific to each tape library due to the various amount and types of hardware installed within the enclosure of the tape library.

Variable speed air conditioning unit program 200 activates a compressor and fans for the variable speed air conditioning unit (204). In this embodiment, variable speed air conditioning unit program 200 receives a signal from a thermostat located within the enclosure of the tape library, where the signal results in variable speed air conditioning unit program 200 activating the compressor and fans for the variable speed air conditioning unit. Variable speed air conditioning unit program 200 activates the fans to direct warm air over an evaporator coil of the variable speed air conditioning unit. The warm air is drawn into the variable speed air conditioning unit from an internal environment of the enclosure of the tape library. As the warm air from the internal environment passes over the evaporator coil, refrigerant liquid in the evaporator coil absorbs heat from the warm air turning the refrigerant liquid into a refrigerant gas. With the evaporator coil absorbing the heat from the warm air, the now cooled air re-enters the internal environment of the enclosure of the tape library. Variable speed air conditioning unit program 200 activates the compressor to increase a pressure and a temperature of the refrigerant gas and sends the refrigerant gas to a condenser coil located in an external environment outside of the enclosure of the tape library. The external environment absorbs the heat from refrigerant gas, converting the refrigerant gas into a liquid, and the refrigerant liquid returns to the evaporator coil completing the cycle.

Variable speed air conditioning unit program 200 monitors environmental values for the tape library (206). In this embodiment, variable speed air conditioning unit program 200 monitors environmental values that include a temperature and humidity levels within the internal environment of the enclosure of the tape library. Variable speed air conditioning unit program 200 receives temperature and humidity values from one or more sensors positioned within the enclosure of the tape library. The position of the one or more sensors is dependent on the configuration of the hardware of the tape library.

Variable speed air conditioning unit program 200 determines whether the environmental values are approaching the target temperature (decision 208). In this embodiment, variable speed air conditioning unit program 200 utilizes the variable speed air conditioning unit profile to determine whether the temperature values are approaching the target temperature value for the internal environment of the tape library. In the event, variable speed air conditioning unit program 200 determines the environmental values are approaching the target temperature (“yes” branch, decision 208), variable speed air conditioning unit program 200 reduces the compressor and the fan speed output (210). In the event, variable speed air conditioning unit program 200 determines the environmental values are not approaching the target temperature (“no” branch, decision 208), variable speed air conditioning unit program 200 determines whether the environmental values are exceeding the target temperature (decision 212).

Variable speed air conditioning unit program 200 reduces the compressor and the fan speed output (210). To prevent evaporator coil from rapidly warming, variable speed air conditioning unit program 200 gradually reduces the compressor and the fan speed output for the variable speed air conditioning unit. In one embodiment, variable speed air conditioning unit program 200 utilizes a reference table to determine a desired output for the compressor and the fan speed based on a temperature sensor value (e.g., 71°) for an internal environment of the tape library and a thermostat setting value (e.g., 72°) for the variable speed air conditioning unit. The reference table provides the desired output to which variable speed air conditioning unit program 200 reduces the compressor and the fan speed output to achieve the thermostat setting value (i.e., the target temperature). In another embodiment, variable speed air conditioning unit program 200 gradually reduces the compressor and the fan speed output in a linear or curved (i.e., parabolic) manner based on the variable speed air conditioning profile for the tape library. In yet another embodiment, variable speed air conditioning unit program 200 gradually reduces the compressor and the fan speed output in a stepped manner based on the variable on the variable speed air conditioning profile for the tape library. Variable speed air conditioning unit program 200 utilizes the variable speed air conditioning unit profile to determine a reduction in a compressor and fan speed output level due to the approaching of the target temperature of the internal environment of the tape library.

As the compressor operates at a constant output level increasing the pressure and the temperature of the refrigerant gas, variable speed air conditioning unit program 200 reduces the compressor output level, resulting in a lower pressurization and temperature increase of the refrigerant gas passing through the compressor and being sent to the condenser coil located in the external environment of the enclosure of the tape library. Similar to the compressor, the fans of the air conditioning unit operate at a constant output level directing air over the evaporator coils. Variable speed air conditioning unit program 200 reduces the fans output level, resulting in less air passing over the evaporator coils which have moisture formed on the coil structure of the evaporator coils. By reducing the output level of the compressor and the fan speed, variable speed air conditioning unit program 200 can gradually warm up the evaporate coils, while preventing a rapid release of moisture into the airstream compared to a typical air conditioning unit that turns the compressor on/off without a gradually output level ramp down.

Variable speed air conditioning unit program 200 determines whether the environmental values are exceeding the target temperature (decision 212). In this embodiment, variable speed air conditioning unit program 200 utilizes the variable speed air conditioning unit profile to determine whether the temperature values exceed the target temperature value for the internal environment of the tape library. In the event, variable speed air conditioning unit program 200 determines the environmental values are exceeding the target temperature (“yes” branch, decision 212), variable speed air conditioning unit program 200 increases the compressor and the fan speed output (214). In the event, variable speed air conditioning unit program 200 determines the environmental values are not exceeding the target temperature (“no” branch, decision 212), variable speed air conditioning unit program 200 reverts and monitors environmental values for the tape library (206).

Variable speed air conditioning unit program 200 increases the compressor and the fan speed output (214). In one embodiment, variable speed air conditioning unit program 200 utilizes a reference table to determine a desired output for the compressor and the fan speed based on a temperature sensor value (e.g., 75°) for an internal environment of the tape library and a thermostat setting value (e.g., 72°) for the variable speed air conditioning unit. The reference table provides the desired output to which variable speed air conditioning unit program 200 increases the compressor and the fan speed output to achieve the thermostat setting value (i.e., the target temperature). In one embodiment, variable speed air conditioning unit program 200 gradually increases the compressor and the fan speed output in a linear or curved (i.e., parabolic) manner based on the variable speed air conditioning profile for the tape library. In another embodiment, variable speed air conditioning unit program 200 gradually increases the compressor and the fan speed output in a stepped manner based on the variable on the variable speed air conditioning profile for the tape library. In yet another embodiment, variable speed air conditioning unit program 200 rapidly increases the compressor and the fan speed output from a lower power out to a higher output based on the variable speed air conditioning profile for the tape library, without doing so in a gradually manner. Variable speed air conditioning unit program 200 utilizes the variable speed air conditioning unit profile to determine an increase in a compressor and fan speed output level due to the environmental temperature values exceeding the target temperature of the internal environment of the tape library.

As the compressor operates at a constant output level increasing the pressure and the temperature of the refrigerant gas, variable speed air conditioning unit program 200 increases the compressor output level, resulting in a higher pressurization and temperature increase of the refrigerant gas passing through the compressor and being sent to the condenser coil located in the external environment of the enclosure of the tape library. Similar to the compressor, the fans of the air conditioning unit operate at a constant output level directing air over the evaporator coils. Variable speed air conditioning unit program 200 increases the fans output level, resulting in more air passing over the evaporator coils. Variable speed air conditioning unit program 200 can increase the compressor and the fan speed output without rapidly introducing moisture back into the airstream from the evaporator coils, since variable speed air conditioning unit program 200 performs the gradually reduction in compressor and fan speed output as previously discussed with respect to (214). Variable speed air conditioning unit program 200 ensures that the evaporator coils remain cool enough during a gradually ramp down period to retain the moisture or greatly reduce an amount of moisture re-introduced into the airstream when variable speed air conditioning unit program 200 increase the compressor and the fan speed output to lower the environmental temperature values within the enclosure of the tape library.

Variable speed air conditioning unit program 200 determines whether the current environmental values match the variable speed air conditioning unit profile (decision 216). In this embodiment, variable speed air conditioning unit program 200 receives new environmental values subsequent to reducing the compressor and the fan speed output (210) or increasing the compressor and the fan speed output (214). Variable speed air conditioning unit program 200 utilizes the new environmental values for the internal environment of the enclosure of the tape library to determine whether further adjustments to the compressor and the fan speed output is required. In the event, variable speed air conditioning unit program 200 determines the current environmental values match the variable speed air conditioning unit profile (“yes” branch, decision 216), variable speed air conditioning unit program 200 reverts and monitors environmental values for the tape library (206). In the event, variable speed air conditioning unit program 200 determines the current environmental values do not match the variable speed air conditioning unit profile (“no” branch, decision 216), variable speed air conditioning unit program 200 reverts and determines whether the environmental values are approaching the target temperature (decision 208).

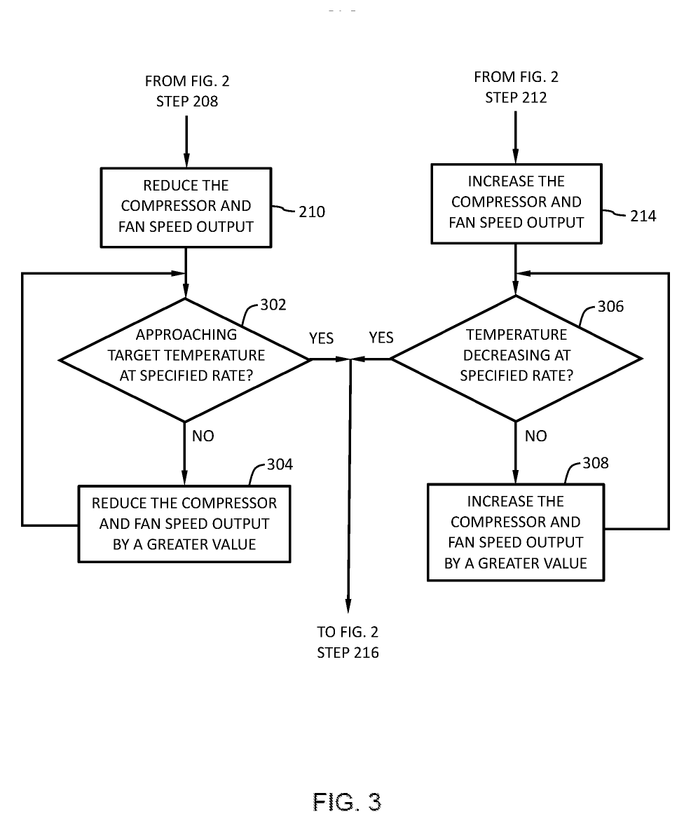

FIG. 3 depicts a flowchart of a variable speed air conditioning unit program for modulating compressor and fan speed output utilizing a variable speed air conditioning unit profile, in accordance with an embodiment of the present invention.

In this embodiment, variable speed air conditioning unit program 200 modulates the compressor and the fan speed output to ensure a temperature value (i.e., environmental value) within the enclosure of the tape library matches a thermostat setting value for the variable speed air conditioning unit. In an instance where variable speed air conditioning unit program 200 determines the environmental values are approaching the target temperature (“yes” branch, decision 208 from FIG. 2), variable speed air conditioning unit program 200 reduces an original output to a new output for the compressor and the fan speed by a first value based on the variable speed air conditioning unit profile for the tape library. In another instance where variable speed air conditioning unit program 200 determines the environmental values are exceeding the target temperature (“yes” branch, decision 212 from FIG. 2), variable speed air conditioning unit program 200 increases an original output to a new output for the compressor and the fan speed output by a first value based on the variable speed air conditioning unit profile for the tape library. It is to be noted that the first value represents a first value for the compressor and a first value for the fan speed, where the first value for the compressor and the first value for the fan speed can be equal or different to one another.

In the instance where variable speed air conditioning unit program 200 reduces the compressor and the fan speed output (210) by the first value from an original output to a new output, variable speed air conditioning unit program 200 determines whether current environmental values within the enclosure of the tape library are approaching the target temperature at a specified rate (decision 302). The specified rate represents a desired rate of a current temperature value for the internal environment of the tape library approaching the target temperature, where the current temperature value is captured in a specified interval (e.g., 30 seconds). For example, variable speed air conditioning unit program 200 receives a current temperature value every 30 seconds and determines a rate for the decreasing temperature of the current temperature values. Variable speed air conditioning unit program 200 compares the specified rate to the determined rate and determines the current temperature values are approaching the target temperature at above the specified rate.

In the event, variable speed air conditioning unit program 200 determines the current environmental values are not approaching the target temperature at the specified rate (“no” branch, decision 302), variable speed air conditioning unit program 200 reduces the compressor and speed output by a greater value (304). In the event, variable speed air conditioning unit program 200 determines the current environmental values are approaching the target temperature at the specified rate (“yes” branch, decision 302), variable speed air conditioning unit program 200 determines whether the current environmental values match the variable speed air conditioning unit profile (decision 216 from FIG. 2).

Variable speed air conditioning unit program 200 reduces the compressor and the fan speed output by a greater value (304). In the embodiment where variable speed air conditioning unit program 200 reduces the compressor and the fan speed output by a first value (e.g. 20%), variable speed air conditioning unit program 200 reduces the compressor and the fan speed output by a second value that is greater than zero. The combination of the first value and the second value represents the greater value by which variable speed air conditioning unit program 200 reduces the compressor and speed output. As previously discussed, variable speed air conditioning unit program 200 can utilize a reference table to determine a new output for the compressor and the fan speed based on one or more of a current temperature value, a target temperature value, a specified rate for the approaching of the target temperature, and a determined rate for the approaching of the target temperature.

In the instance where variable speed air conditioning unit program 200 increases the compressor and the fan speed output (214) by the first value from an original output to a new output, variable speed air conditioning unit program 200 determines whether current environmental values indicate a temperature decreasing at a specified rate (decision 306). The specified rate represents a desired rate of a current temperature value for the internal environment of the tape library decreasing to the target temperature, where the current temperature value is captured in a specified interval (e.g., 30 seconds). For example, variable speed air conditioning unit program 200 receives a current temperature value every 30 seconds and determines a rate for the decreasing temperature of the current temperature values. Variable speed air conditioning unit program 200 compares the specified rate to the determined rate and determines the current temperature values are decreasing below the specified rate.

In the event, variable speed air conditioning unit program 200 determines the current environmental values indicate the temperature is not decreasing at the specified rate (“no” branch, decision 306), variable speed air conditioning unit program 200 increases compressor and fan speed output by a greater value (308). In the event, variable speed air conditioning unit program 200 determines the current environmental values indicate the temperature is decreasing at the specified rate (“yes” branch, decision 306), variable speed air conditioning unit program 200 determines whether the current environmental values match the variable speed air conditioning unit profile (decision 216 from FIG. 2).

Variable speed air conditioning unit program 200 increases compressor and fan speed output by a greater value (308). In the embodiment where variable speed air conditioning unit program 200 increases the compressor and the fan speed output by a first value (e.g. 30%), variable speed air conditioning unit program 200 increases the compressor and speed output by a second value that is greater than zero. The combination of the first value and the second value represents the greater value by which variable speed air conditioning unit program 200 increases the compressor and the fan speed output. As previously mentioned, variable speed air conditioning unit program 200 can utilize a reference table to determine a new output for the compressor and the fan speed based on one or more of a current temperature value, a target temperature value, a specified rate for the decreasing temperature values, and a determined rate for the decreasing temperature values.

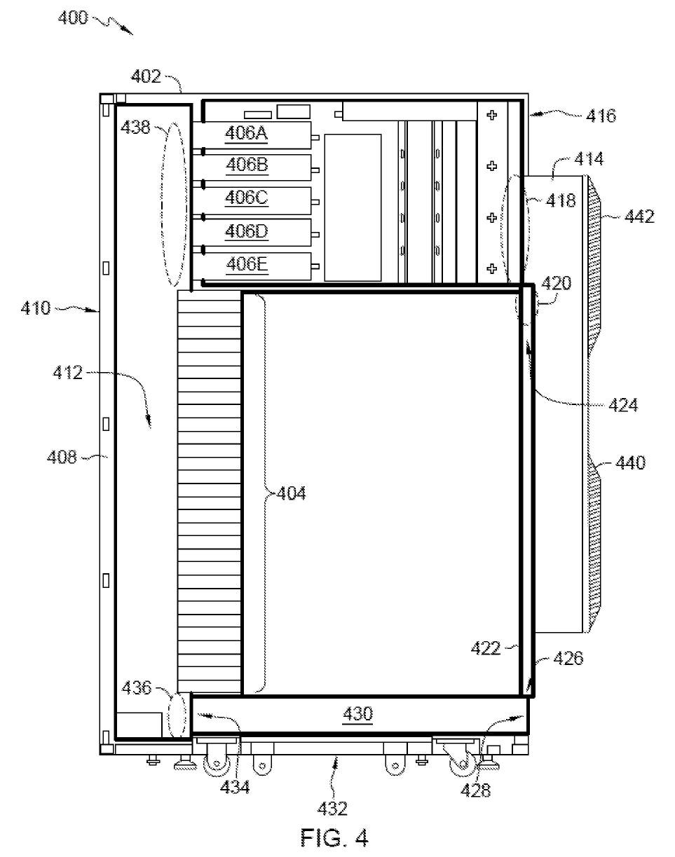

FIG. 4 depicts a side view of a tape library with an air conditioning unit operating with a variable speed air conditioning unit program, in accordance with an embodiment of the present invention. Tape library 400 includes enclosure 402 housing various hardware that includes tape cartridges 404 and tape drives 406A, 406B, 406C, 406D, and 406E. Door 408 for accessing tape cartridges 404 and tape drives 406A-406E is located on first side 410 of enclosure 402, where front air plenum 412 is located between tape cartridges 404 and tape drives 406A-406E. Front air plenum 412 is also the space where the robotics for the automated tape library moves and performs its robotic actions of picking and placing tape cartridges. Variable speed air conditioning unit 414 is located on second side 416 of enclosure 402, opposite door 408 located on first side 410 of enclosure 402. Variable speed air conditioning unit 414 is coupled to enclosure 402 on second side 416, such that, variable speed air conditioning unit 414 is suspended from enclosure 402. Internal air inlet area 418 of variable speed air conditioning unit 414 represents a first zone where variable speed air conditioning unit 414 draws in airflow from a rear portion of tape drives 406A-406E. Internal air outlet area 420 of variable speed air conditioning unit 414 represents a second zone where variable speed air conditioning unit 414 directs cooled area into rear air plenum 422 located on second side 416 between enclosure 402 and variable speed air conditioning unit 414.

First end 424 of rear air plenum 422 is connected to variable speed air conditioning unit 414 and second end 426 of rear air plenum 422 is connected to first end 428 of lower air plenum 430. Lower air plenum 430 is positioned above lower side 432 of enclosure 402 and beneath tape cartridges 404. Second end 434 of lower air plenum 430 leads to lower area 436 of front air plenum 412 and upper area 438 of front air plenum 412 leads to a region where air is pulled into tape drives 406A-406E. Variable speed air conditioning unit 414 includes external air inlet 440 for drawing in external air towards condenser coils positioned within variable speed air conditioning unit 414 and external air outlet 442 for exhausting heated air after passing through the condenser coils. Front air plenum 412 can include one or more temperature sensors electrically coupled to (e.g., cabled to) variable speed air conditioning unit 414 for capturing environmental values within enclosure 402 of tape library 400. Front air plenum 412 can also include a thermostat for controlling variable speed air conditioning unit 414 or alternatively, the thermostat can be located directly on variable speed air conditioning unit 414, near air inlet area 418.

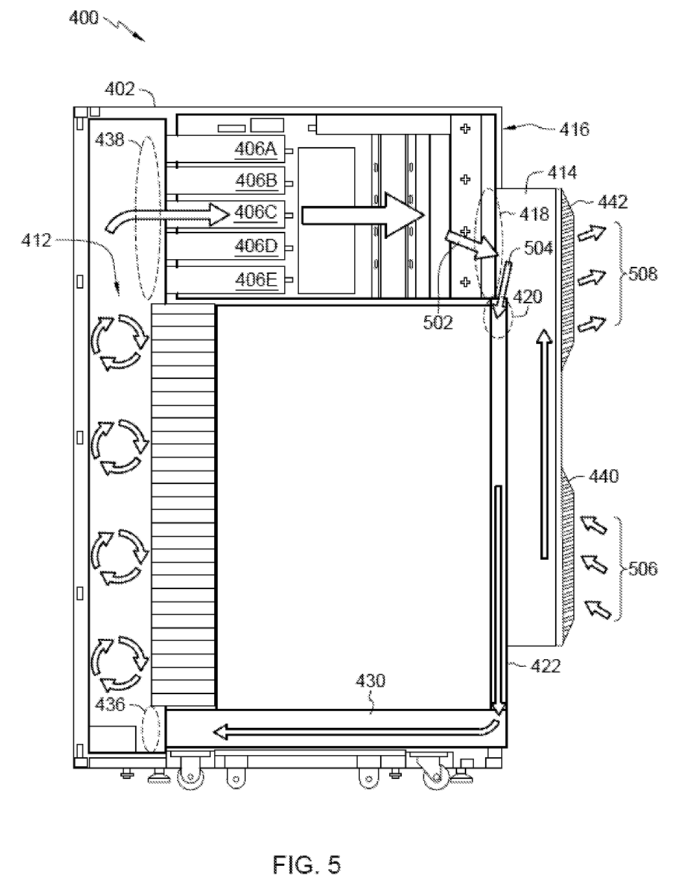

FIG. 5 depicts a side view for airflow internal and external to a tape library with an air conditioning unit operating with a variable speed air conditioning unit program, in accordance with an embodiment of the present invention. In this embodiment, variable speed air conditioning unit program 200 receives a variable speed air conditioning unit profile for a tape library and activates a compressor and fans for variable speed air conditioning unit 414 of tape library 400. Variable speed air conditioning unit program 200 activates fans to direct warm air over an evaporator coil positioned within variable speed air conditioning unit 414, where internal air inlet area 418 of variable speed air conditioning unit 414 represents a first zone where variable speed air conditioning unit 414 draws in internal airflow 502. As the warm air (i.e., internal airflow 502) from the internal environment passes over the evaporator coil, refrigerant liquid in the evaporator coil absorbs heat from the warm air turning the refrigerant liquid into a refrigerant gas. With the evaporator coil absorbing the heat from the warm air, the now internal cooled airflow 504 exits internal air outlet area 420 of variable speed air conditioning unit 414 traveling down rear air plenum 422 towards lower air plenum 430. Internal cooled air exits lower air plenum 430 at lower area 436 of front air plenum 412 and mixes with existing warmer air located in front air plenum 412. Tape drives 406A-406E draw in air from front air plenum 412 in upper area 438, where the air passed through tape drives 406A-406E back towards air inlet area 418 of variable speed air conditioning unit 414. Variable speed air conditioning unit 414 draws in external air 506 at external air inlet 440 from the external environment towards condenser coils positioned within variable speed air conditioning unit 414. External air 506 passes through the condenser coils absorbing the heat from the refrigerant gas and heated external air 508 exits external air outlet 442 back into the external environment.

Variable speed air conditioning unit program 200 monitors environmental values for an internal environment of enclosure 402 of tape library 400 and determines the environmental values are approaching a target temperature for the internal environment. Variable speed air conditioning unit program 200 reduces the compressor and the fan speed output of variable speed air conditioning unit 414 based on a variable speed air conditioning profile. As previously discussed with respect to FIG. 2, as the compressor operates at a constant output level increasing the pressure and the temperature of the refrigerant gas, variable speed air conditioning unit program 200 reduces the compressor output level, resulting in a lower pressurization and temperature increase of the refrigerant gas passing through the compressor and being sent to the condenser coil located in the external environment of enclosure 402 of tape library 400. Similar to the compressor, the fans of variable speed air conditioning unit 414 operate at a variable output level directing air over the evaporator coils. Variable speed air conditioning unit program 200 reduces the fans output level, resulting in less air passing over the evaporator coils which have moisture formed on the coil structure of the evaporator coils. By reducing the output level of the compressor and the fan speed, variable speed air conditioning unit program 200 can gradually warm up the evaporate coils, while preventing a rapid release of moisture into the airstream at air inlet area 418 of variable speed air conditioning unit 414 compared to a typical air conditioning unit that turns the compressor on/off without a gradually output level ramp down.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
receiving environmental values for an internal environment of an enclosure of a tape library;
determining the environmental values are approaching a target temperature for the enclosure of the tape library; and
reducing an original output of a compressor and a fan speed of a variable speed air conditioning unit of the tape library to a new output.

2. The method of claim 1, further comprising:
wherein reducing the original output of the compressor and the fan speed for the variable speed air conditioning unit of the tape library is based on a variable speed air conditioning unit profile for the tape library,
wherein reducing the original output of the compressor and the fan speed for the variable speed air conditioning unit of the tape library is based on a first value for the compressor and a first value for the fan speed.

3. The method of claim 2, further comprising:
receiving the variable speed air conditioning unit profile of the tape library is based on a variable speed air conditioning unit profile for the tape library;
activating the compressor and fans for the variable speed air conditioning unit of the tape library; and
monitoring the environmental values for the internal environment of the enclosure of the tape library based on the variable speed air conditioning unit profile.

4. The method of claim 2, further comprising:
determining new environmental values are not approaching the target temperature for the enclosure of the tape library at a specified rate; and
reducing the new output of the compressor and the fan speed for the variable speed air conditioning unit of the tape library by a second value for the compressor and by a second value for the fan speed, wherein the second value for the compressor and the second value for the fan speed are each greater than zero.

5. The method of claim 4, wherein reducing the new output of the compressor and the fan speed for the variable speed air conditioning unit of the tape library is based on a reference table for a temperature value for the tape library and a thermostat setting value for the variable speed air conditioning unit.

6. The method of claim 5, wherein the first value for the compressor is different from the first value for the fan speed, and the second value for the compressor is different from the second value for the fan speed.

7. The method of claim 2, wherein reducing the original output of the compressor and the fan speed for the variable speed air conditioning unit of the tape library is based on a reference table for a temperature value for the tape library and a thermostat setting value for the variable speed air conditioning unit.

8. A computer program product comprising:
one or more computer readable storage media;
program instructions, stored on at least one of the one or more computer readable storage media, to receive environmental values for an internal environment of an enclosure of a tape library;
program instructions, stored on at least one of the one or more computer readable storage media, to determine the environmental values are approaching a target temperature for the enclosure of the tape library; and
program instructions, stored on at least one of the one or more computer readable storage media, to reduce an original output of a compressor and a fan speed of a variable speed air conditioning unit of the tape library to a new output.

9. The computer program product of claim 8, further comprising:
wherein program instructions to reduce the original output of the compressor and the fan speed for the variable speed air conditioning unit of the tape library is based on a variable speed air conditioning unit profile for the tape library,
wherein program instructions to reduce the original output of the compressor and the fan speed for the variable speed air conditioning unit of the tape library is based on a first value for the compressor and a first value for the fan speed.

10. The computer program product of claim 9, further comprising:
program instructions, stored on at least one of the one or more computer readable storage media, to receive the variable speed air conditioning unit profile of the tape library is based on a variable speed air conditioning unit profile for the tape library;
program instructions, stored on at least one of the one or more computer readable storage media, to activate the compressor and fans for the variable speed air conditioning unit of the tape library; and
program instructions, stored on at least one of the one or more computer readable storage media, to monitor the environmental values for the internal environment of the enclosure of the tape library based on the variable speed air conditioning unit profile.

11. The computer program product of claim 9, further comprising:
program instructions, stored on at least one of the one or more computer readable storage media, to determine new environmental values are not approaching the target temperature for the enclosure of the tape library at a specified rate; and
program instructions, stored on at least one of the one or more computer readable storage media, to reduce the new output for the compressor and the fan speed for the variable speed air conditioning unit of the tape library by a second value for the compressor and by a second value for the fan speed, wherein the second value for the compressor and the second value for the fan speed are each greater than zero.

12. The computer program product of claim 11, wherein program instructions, stored on at least one of the one or more computer readable storage media, to reduce the new output of the compressor and the fan speed for the variable speed air conditioning unit of the tape library is based on a reference table for a temperature value for the tape library and a thermostat setting value for the variable speed air conditioning unit.

13. The computer program product of claim 12, wherein the first value for the compressor is different from the first value for the fan speed, and the second value for the compressor is different from the second value for the fan speed.

14. The computer program product of claim 9, wherein program instructions, stored on at least one of the one or more computer readable storage media, to reduce the original output of the compressor and the fan speed for the variable speed air conditioning unit of the tape library is based on a reference table for a temperature value for the tape library and a thermostat setting value for the variable speed air conditioning unit.

15. A computer system comprising:
one or more processors, one or more computer readable memories and one or more computer readable storage media;
program instructions, stored on at least one of the one or more computer readable storage media for execution by at least one of the one or more processors via at least one of the one or more computer readable memories, to receive environmental values for an internal environment of an enclosure of a tape library;
program instructions, stored on at least one of the one or more computer readable storage media for execution by at least one of the one or more processors via at least one of the one or more computer readable memories, to determine the environmental values are approaching a target temperature for the enclosure of the tape library; and
program instructions, stored on at least one of the one or more computer readable storage media for execution by at least one of the one or more processors via at least one of the one or more computer readable memories, to reduce an original output of a compressor and a fan speed of a variable speed air conditioning unit of the tape library to a new output.

16. The computer system of claim 15, further comprising:
wherein program instructions, stored on at least one of the one or more computer readable storage media for execution by at least one of the one or more processors via at least one of the one or more computer readable memories, to reduce the original output of the compressor and the fan speed for the variable speed air conditioning unit of the tape library is based on a variable speed air conditioning unit profile for the tape library,
wherein program instructions, stored on at least one of the one or more computer readable storage media for execution by at least one of the one or more processors via at least one of the one or more computer readable memories, to reduce the original output of the compressor and the fan speed for the variable speed air conditioning unit of the tape library is based on a first value for the compressor and a first value for the fan speed.

17. The computer system of claim 16, further comprising:
program instructions, stored on at least one of the one or more computer readable storage media for execution by at least one of the one or more processors via at least one of the one or more computer readable memories, to receive the variable speed air conditioning unit profile of the tape library is based on a variable speed air conditioning unit profile for the tape library;
program instructions, stored on at least one of the one or more computer readable storage media for execution by at least one of the one or more processors via at least one of the one or more computer readable memories, to activate the compressor and fans for the variable speed air conditioning unit of the tape library; and
program instructions, stored on at least one of the one or more computer readable storage media for execution by at least one of the one or more processors via at least one of the one or more computer readable memories, to monitor the environmental values for the internal environment of the enclosure of the tape library based on the variable speed air conditioning unit profile.

18. The computer system of claim 16, further comprising:
program instructions, stored on at least one of the one or more computer readable storage media for execution by at least one of the one or more processors via at least one of the one or more computer readable memories, to determine new environmental values are not approaching the target temperature for the enclosure of the tape library at a specified rate; and
program instructions, stored on at least one of the one or more computer readable storage media for execution by at least one of the one or more processors via at least one of the one or more computer readable memories, to reduce the new output for the compressor and the fan speed for the variable speed air conditioning unit of the tape library by a second value for the compressor and by a second value for the fan speed, wherein the second value for the compressor and the second value for the fan speed are each greater than zero.

19. The computer system of claim 18, wherein program instructions, stored on at least one of the one or more computer readable storage media for execution by at least one of the one or more processors via at least one of the one or more computer readable memories, to reduce the new output of the compressor and the fan speed for the variable speed air conditioning unit of the tape library is based on a reference table for a temperature value for the tape library and a thermostat setting value for the variable speed air conditioning unit.

20. The computer system of claim 19, wherein the first value for the compressor is different from the first value for the fan speed, and the second value for the compressor is different from the second value for the fan speed.

21. The computer system of claim 16, wherein program instructions, stored on at least one of the one or more computer readable storage media for execution by at least one of the one or more processors via at least one of the one or more computer readable memories, to reduce the original output of the compressor and the fan speed for the variable speed air conditioning unit of the tape library is based on a reference table for a temperature value for the tape library and a thermostat setting value for the variable speed air conditioning unit.

22. A method comprising:
receiving environmental values for an internal environment of an enclosure of a tape library;
determining the environmental values are exceeding a target temperature for the enclosure of the tape library; and
increasing an original output of a compressor and a fan speed of a variable speed air conditioning unit of the tape library to a new output.

23. The method of claim 22, further comprising:
wherein increasing the original output of the compressor and the fan speed for the variable speed air conditioning unit of the tape library is based on a variable speed air conditioning unit profile for the tape library,
wherein increasing the original output of the compressor and the fan speed for the variable speed air conditioning unit of the tape library is based on a first value for the compressor and a first value for the fan speed.

24. The method of claim 23, further comprising:
determining new environmental values are not decreasing at a specified rate for the enclosure of the tape library at a specified rate; and
increasing the new output for the compressor and the fan speed for the variable speed air conditioning unit of the tape library by a second value for the compressor and by a second value for the fan speed, wherein the second value for the compressor and the second value for the fan speed are each greater than zero.

25. The method of claim 23, wherein increasing the original output and the new output for the compressor and the fan speed for the variable speed air conditioning unit of the tape library based on a reference table for a temperature value for the tape library and a thermostat setting value for the variable speed air conditioning unit.
